(19) United States
(12) Patent Application Publication
(10) Pub. No.: US 2025/0133779 A1
(43) Pub. Date: Apr. 24, 2025

(54) SEMICONDUCTOR DEVICE WITH COUPLER STRUCTURE

(71) Applicant: INTERNATIONAL BUSINESS MACHINES CORPORATION, ARMONK, NY (US)

(72) Inventors: Adinath Shantinath Narasgond, Yonkers, NY (US); Jae-Woong Nah, Closter, NJ (US); David Abraham, Yorktown Heights, NY (US); John Michael Cotte, New Fairfield, CT (US); So-Young Kim, White Plains, NY (US)

(21) Appl. No.: 18/493,765

(22) Filed: Oct. 24, 2023

(51) Int. Cl. H01L 29/66; H01L 23/00; H01L 23/498; H01L 23/50; H01L 23/60; H01L 25/16

(52) U.S. Cl. CPC H10D 48/383; H01L 23/49827; H01L 23/50; H01L 23/60; H01L 24/08; H01L 24/16; H01L 25/16; H01L 2224/08225; H01L 2224/16146; H01L 2224/16227; H01L 2924/1011; H01L 2924/14

(57) ABSTRACT

A semiconductor device includes a device wafer having a first side and a second side, a bus located on the second side of the device wafer, and a top wafer having a first side and a second side. A plurality of qubits are located on the first side of the device wafer, and a first plurality of bump bonds located on the first side of the top wafer bond the top wafer with the second side of the device wafer.

### BACKGROUND

### Technical Field

The present disclosure generally relates to quantum devices, and more particularly, to quantum devices with coupler structures and methods of creation thereof.

### Description of the Related Art

Quantum chips exploit the principles of superposition and entanglement to perform complex computations and cryptographic operations beyond classical computers' capabilities. Quantum chips typically include quantum bits (qubits) as their fundamental information units. Qubits exist in a coherent superposition of states, enabling them to represent multiple values simultaneously. This unique property enables quantum chips to perform parallel computations, potentially leading to significant advancements in various fields such as optimization, simulation, and cryptography.

### SUMMARY

According to an embodiment, a semiconductor device includes a device wafer having a first side and a second side, a bus located on the second side of the device wafer, and a top wafer having a first side and a second side. A plurality of qubits are located on the first side of the device wafer. A first plurality of bump bonds, located on the first side of the top wafer, bond the top wafer with the second side of the device wafer.

In some embodiments, which can be combined with the previous embodiment, the semiconductor device further includes an interposer with a first side and a second side. A second plurality of bump bonds located on the second side of the interposer bond connects the interposer with the first side of the device wafer.

In some embodiments, which can be combined with one or more previous embodiments, the bus connects the plurality of qubits via a first set of through-silicon vias (TSVs).

In some embodiments, which can be combined with one or more previous embodiments, the top wafer further includes a first metal layer between the first plurality of bump bonds.

In some embodiments, which can be combined with one or more previous embodiments, the interposer further includes a second metal layer between the second plurality of bump bonds, and a second set of TSVs.

In some embodiments, which can be combined with one or more previous embodiments, the first plurality of bump bonds and the second plurality of bump bonds are made of different materials.

In some embodiments, which can be combined with one or more previous embodiments, the semiconductor device includes a carrier wafer on the first side of the interposer.

According to another embodiment, a method for forming a semiconductor device includes forming a device wafer with a first side and a second side. A plurality of qubits are on the first side of the device wafer, and a bus is on the second side of the device wafer. A carrier wafer is removed from the second side of the device wafer. A top wafer with a first side and a second side is formed. The first side of the top wafer is bonded with the second side of the device wafer.

In some embodiments, which can be combined with the previous embodiment, the method includes connecting the plurality of qubits via a first set of through-silicon vias (TSVs) by way of the bus.

In some embodiments, which can be combined with one or more previous embodiments, the method includes forming a first plurality of bump bonds on the first side of the top wafer, and bonding the top wafer and the device wafer via the first plurality of bump bonds.

In some embodiments, which can be combined with one or more previous embodiments, the method includes forming an interposer having a first side and a second side, forming a second plurality of bump bonds on the second side of the interposer, and bonding the interposer with the first side of the device wafer via the second plurality of bump bonds.

In some embodiments, which can be combined with one or more previous embodiments, the method includes forming a first metal layer on the top wafer between the first plurality of bump bonds.

In some embodiments, which can be combined with one or more previous embodiments, the method includes forming a carrier wafer on the first side of the interposer.

In some embodiments, which can be combined with one or more previous embodiments, the method includes forming a second metal layer on the interposer between the second plurality of bump bonds, and forming a second set of TSVs on the interposer.

In some embodiments, which can be combined with one or more previous embodiments, the first plurality of bump bonds and the second plurality of bump bonds are made of different materials.

According to yet another embodiment, a semiconductor device includes a device wafer having a first side and a second side, a top wafer having a first side and a second side, and a bus located on the first side of the stop wafer. A plurality of qubits are located on the first side of the device wafer, and a first plurality of bump bonds located on the first side of the top wafer bond the top wafer with the second side of the device wafer.

In some embodiments, which can be combined with the previous embodiment, the semiconductor device includes an interposer having a first side and a second side. A second plurality of bump bonds located on the second side of the interposer bond the interposer with the first side of the device wafer.

In some embodiments, which can be combined with one or more previous embodiments, the bus connects the plurality of qubits.

In some embodiments, which can be combined with one or more previous embodiments, the interposer further includes a metal layer between the second plurality of bump bonds, and a set of TSVs. The first plurality of bump bonds and the second plurality of bump bonds are made of different materials.

In some embodiments, which can be combined with one or more previous embodiments, the semiconductor device includes a first carrier wafer on the first side of the interposer and a second carrier wafer on the second side of the top wafer.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 illustrates a semiconductor device, in accordance with some embodiments.

FIG. 2 illustrates a semiconductor device with a coupler structure, in accordance with some embodiments.

FIGS. 3A-3B illustrate acts for forming a semiconductor device, in accordance with some embodiments.

FIGS. 4A-4C illustrate acts for forming a semiconductor device, in accordance with some embodiments.

FIGS. 5A-5B illustrate acts in the forming a semiconductor device, in accordance with some embodiments.

FIG. 6 illustrates a block diagram of a method for forming a semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature, and their shapes do not necessarily illustrate the actual shape of a region of a device and do not limit the scope.

It is to be understood that other embodiments may be used, and structural or logical changes may be made without departing from the spirit and scope defined by the claims. The description of the embodiments is not limiting. In particular, elements of the embodiments described hereinafter may be combined with elements of different embodiments.

As used herein, certain terms are used indicating what may be considered an idealized behavior, such as, for example, “lossless,” “semiconductor,” or “semiconductor,” which are intended to cover functionality that may not be exactly ideal but are within acceptable margins for a given application. For example, a certain level of loss or tolerance may be acceptable such that the resulting materials and structures may still be referred to by these “idealized” terms.

According to an embodiment, a semiconductor device includes a device wafer having a first side and a second side, a bus located on the second side of the device wafer, and a top wafer having a first side and a second side. A plurality of qubits are located on the first side of the device wafer, and a first plurality of bump bonds located on the first side of the top wafer bond the top wafer with the second side of the device wafer. The device wafer is de-bonded from the carrier wafer, which offers additional chip bonding capabilities.

In some embodiments, which can be combined with the previous embodiment, the semiconductor device further includes an interposer having a first side and a second side. A second plurality of bump bonds located on the second side of the interposer bond the interposer with the first side of the device wafer. Unlike conventional semiconductor devices, the device wafer is bonded with the interposer and the top wafer.

In some embodiments, which can be combined with one or more previous embodiments, the bus connects the plurality of qubits via a first set of through-silicon vias (TSVs). Utilizing the TSVs ensures the connectivity between the qubits.

In some embodiments, which can be combined with one or more previous embodiments, the top wafer further includes a first metal layer between the first plurality of bump bonds. Thus, the first set of bump bonds are connected to each other.

In some embodiments, which can be combined with one or more previous embodiments, the interposer further includes a second metal layer between the second plurality of bump bonds, and a second set of TSVs. Thus, the second set of bum bonds are connected to each other.

In some embodiments, which can be combined with one or more previous embodiments, the first plurality of bump bonds and the second plurality of bump bonds are made of different materials. This enables the fabrication steps to be performed independently.

In some embodiments, which can be combined with one or more previous embodiments, the semiconductor device includes a carrier wafer on the first side of the interposer. Thus, the device wafer is not directly connected to the carrier wafer.

According to another embodiment, a method for forming a semiconductor device includes forming a device wafer having a first side and a second side, forming a plurality of qubits on the first side of the device wafer, forming a bus on the second side of the device wafer, removing a carrier wafer from the second side of the device wafer, forming a top wafer having a first side and a second side, and bonding the first side of the top wafer with the second side of the device wafer. Thus, the device wafer is de-bonded from the carrier wafer, which offers additional chip bonding capabilities.

In some embodiments, which can be combined with the previous embodiment, the method includes connecting the plurality of qubits via a first set of through-silicon vias (TSVs) by way of the bus. Utilizing the TSVs ensures the connectivity between the qubits.

In some embodiments, which can be combined with one or more previous embodiments, the method includes forming a first plurality of bump bonds on the first side of the top wafer, and bonding the top wafer and the device wafer via the first plurality of bump bonds. Utilizing the first set of bump bonds ensures that the top wafer and the device wafer are connected.

In some embodiments, which can be combined with one or more previous embodiments, the method includes forming an interposer having a first side and a second side, forming a second plurality of bump bonds on the second side of the interposer, and bonding the interposer with the first side of the device wafer via the second plurality of bump bonds. Thus, instead of being connected to a carrier wafer, the device wafer is connected to the interposer.

In some embodiments, which can be combined with one or more previous embodiments, the method includes forming a first metal layer on the top wafer between the first plurality of bump bonds. Thus, the first set of bump bonds are connected to each other.

In some embodiments, which can be combined with one or more previous embodiments, the method includes forming a carrier wafer on the first side of the interposer. Thus, the device wafer is not directly connected to the carrier wafer.

In some embodiments, which can be combined with one or more previous embodiments, the method includes forming a second metal layer on the interposer between the second plurality of bump bonds, and forming a second set of TSVs on the interposer. Thus, the second set of bump bonds are connected to each other.

In some embodiments, which can be combined with one or more previous embodiments, the first plurality of bump bonds and the second plurality of bump bonds are made of different materials. This enables the fabrication steps to be performed independently.

According to yet another embodiment, a semiconductor device includes a device wafer having a first side and a second side, a top wafer having a first side and a second side, and a bus located on the first side of the top device. A plurality of qubits are located on the first side of the device wafer, and a first plurality of bump bonds located on the first side of the top wafer bond the top wafer with the second side of the device wafer. Thus, the device wafer is de-bonded from the carrier wafer, which offers additional chip bonding capabilities.

In some embodiments, which can be combined with the previous embodiment, the semiconductor device includes an interposer having a first side and a second side. A second plurality of bump bonds located on the second side of the interposer bond the interposer with the first side of the device wafer. Thus, unlike conventional devices, the device wafer is connected to the interposer and the top wafer.

In some embodiments, which can be combined with one or more previous embodiments, the bus connects the plurality of qubits. Thus, the qubits are connected to each other.

In some embodiments, which can be combined with one or more previous embodiments, the interposer further includes a metal layer between the second plurality of bump bonds, and a set of TSVs. The first plurality of bump bonds and the second plurality of bump bonds are made of different materials. This enables the fabrication processes of the first set of bump bonds and the second set of bump bonds to be performed independently.

In some embodiments, which can be combined with one or more previous embodiments, the semiconductor device includes a first carrier wafer on the first side of the interposer and a second carrier wafer on the second side of the top wafer. Thus, the device wafer is not directly connected to the carrier wafer.

Quantum chips are advanced integrated circuits designed to harness the principles of quantum mechanics for computation, information processing, and other quantum-related tasks. Unlike classical bits, which represent information as either 0 or 1, quantum chips use quantum bits or qubits that can exist in a superposition of both states simultaneously. This unique property allows quantum chips to perform parallel computations, potentially solving complex problems more efficiently than classical computers.

Quantum chips typically include various components, including qubits, control electronics, readout devices, and interconnects. Qubits are the heart of quantum chips and can be realized using different physical systems such as semiconductor circuits, trapped ions, or topological qubits. Control electronics manage the manipulation and interactions of qubits, while readout devices measure the quantum states of qubits to obtain useful information.

Quantum computation utilizes a qubit as its essential unit instead of a classical computing bit. The qubit (e.g., quantum binary digit) is the quantum-mechanical analog of the classical bit. Whereas classical bits can employ only one of two basis states (e.g., 0 or 1), qubits can employ superpositions of those basis states, allowing several qubits to theoretically hold exponentially more information than the same number of classical bits.

Semiconductor devices are used in a wide range of electronic and electro-optical applications. Integrated circuits (ICs) can be formed from different circuit configurations of semiconductor devices such as transistors, capacitors, resistors, and conductive interconnect layers formed on semiconductor wafers. The conductive interconnect layers, along with semiconductor devices, are fabricated on a single wafer. Such interconnect layers are connected by a network of holes (or vias) formed through the IC. In particular, a through-silicon via (TSV) is an electrical contact that passes completely through a semiconductor wafer.

In the realm of semiconductor chips, device wafers are typically around 100 micrometers thick and are supported by a silicon handler, i.e., a carrier wafer. The carrier wafer that is attached to one side of the device wafer provides mechanical support for the device wafer. However, the existence of the carrier wafer on one side of the device wafer limits the use of one surface of the device wafer to which the handler is attached. The present disclosure offers a semiconductor device in which the carrier wafer is removed from the wafer device. As such, the disclosed semiconductor device provides a high-quality surface that can be used for connecting distant qubits.

To that end, a high-quality surface is formed by debonding the carrier wafer from the device wafer, which can then be used to split the plane and stack additional semiconductor devices. This enables connecting distant qubits and improves the performance of qubit chips. Further, the disclosed semiconductor device can protect the qubits from spurious modes outside of the package and isolate the couplers from the qubits.

Accordingly, the teachings herein provide methods and systems of semiconductor device formation with coupler structures. The techniques described herein may be implemented in a number of ways. Example implementations are provided below with reference to the following figures.

Example Semiconductor Device with Couplers Structure

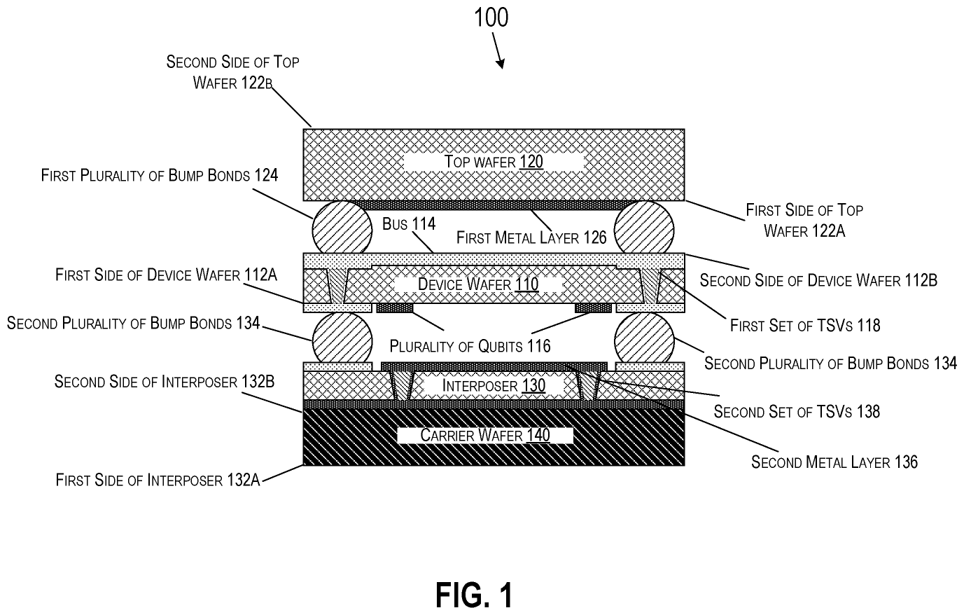

Reference now is made to FIG. 1, which is a simplified cross-section view of a semiconductor device 100, consistent with an illustrative embodiment. It is worth mentioning that, hereinafter, a first side refers to a bottom surface, and a second side refers to a top surface of an element.

In various embodiments, the semiconductor device 100 can include a device wafer 110 and a top wafer 120. The device wafer has a first side 112a, i.e., a bottom surface, a second side 112b, i.e., a top surface, and a bus 114, which is located on the second side 112b of the device wafer 110. The top wafer 120 has a first side 122a and a second side 122b. A plurality of qubits 116 are located on the first side 112a of the device wafer 110, and a first plurality of bump bonds 124 are located on the first side 122a of the top wafer 120. The first plurality of bump bonds 124 bond the first side 122a of the top wafer 120 with the second side 112b of the device wafer 110. The top wafer 120 can be a shielding wafer or a device wafer.

In some embodiments, the bus 114 connects the plurality of qubits 116 via a first set of through-silicon vias (TSVs) 118. The bus, i.e., the c-coupler, can be formed over the second side 112b of the device wafer 110, i.e., the top surface of the device wafer 110, as shown in FIG. 1, and can be extended to the first side 110a of the device wafer 110, i.e., the bottom surfacer of the wafer device 110 as shown in FIG. 1, via the first set of TSVs 118. The first set of TSVs 118 are vertical interconnections that pass through the silicon substrate of the device wafer 110 and connect circuitry on different sides of the device wafer 110. The bus 114 can be in direct contact with the first set of TSVs 118, the first plurality of bump bonds 124.

In some embodiments, the top wafer 120 includes pads, which are conductive areas or regions on the top wafer's surface that serve as contact points for electrical connections. These pads can be made of metal, such as aluminum or copper, and are used for making electrical connections to other devices. The top wafer 120 formed over the device wafer 110 can create a fully enclosed metal channel in which long-range connections are fabricated.

The first plurality of bump bonds 124 can be formed from a first low-temperature solder material and provided with a size and/or shape that enables an electrical connection to be made at the point of contact. The first plurality of bump bonds 124 may be utilized to mechanically and electrically connect the top wafer 120 to the device wafer 110. In some embodiments, the top wafer 120 further includes a first metal layer 126 which is extended between the first plurality of bump bonds 124.

In some embodiments, the semiconductor device 100 further includes an interposer 130. The interposer 130 has a first side 132a and a second side 132b. A second plurality of bump bonds 134 are located on the second side 132b of the interposer 130. The second plurality of bump bonds 134 bond, i.e., connect the second side 132b of the interposer 130 with the first side 112a of the device wafer 110. The interposer 130 can include multi-level wiring (MLW) on the first side 132a. The MLW can be connected by TSVs.

The second plurality of bump bonds 134 can be formed from a second low-temperature solder material, which can be different from the low-temperature solder material used to make the first plurality of bump bonds 124, and provided with a size and/or shape that enables an electrical connection to be made at the point of contact. The second plurality of bump bonds 134 may be utilized to mechanically and electrically connect the interposer 130 to the device wafer 110. In some embodiments, the first plurality of bump bonds 124 and the second plurality of bump bonds 134 are made of different materials. That is, the first low-temperature solder material is different from the second low-temperature solder material. The first plurality of bump bonds 124 and the second plurality of bump bonds 134 can be made of the same material and with the same size. Alternatively, the first plurality of bump bonds 124 and the second plurality of bump bonds 134 can be made of the same material with different sizes. In some embodiments, the number of the first plurality of bump bonds 124 and the number of the second plurality of bump bonds 134 can be different. These variations of the first plurality of bump bonds 124 and the second plurality of bump bonds 134 can allow the sequential bonding of layers without requiring the crushing of the first plurality of bump bonds 124 while bonding the second plurality of bump bonds 134.

In some embodiments, the interposer 130 further includes a second metal layer 136 which is extended between the second plurality of bump bonds 134. The interposer 130 can include a second set of TSVs 138.

In some embodiments, the semiconductor device 100 includes a carrier wafer 140 on the first side 132a of the interposer 130. The carrier wafer 140 can provide structural stability to the semiconductor device 100.

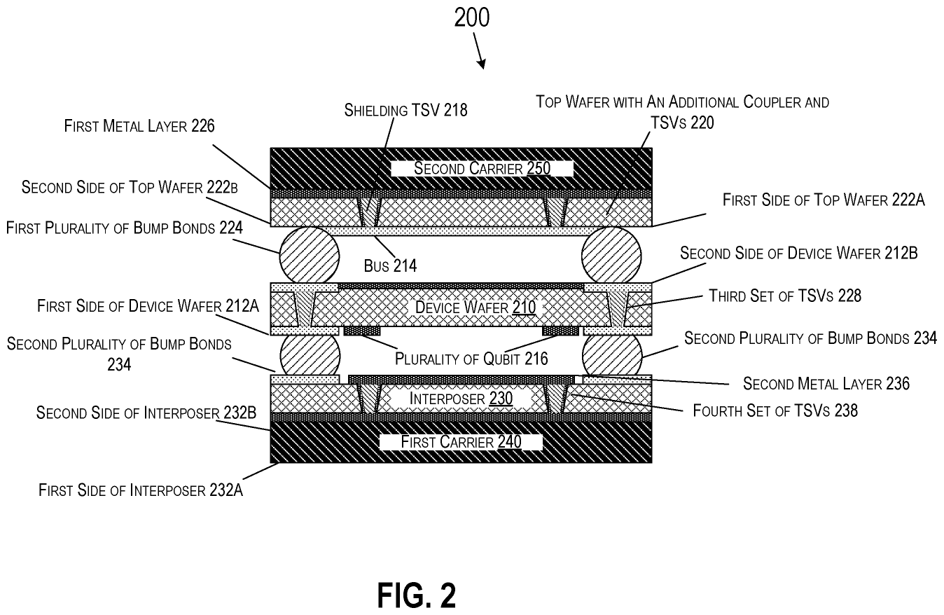

FIG. 2 illustrates a semiconductor device with a coupler structure, in accordance with some embodiments. The semiconductor device 200 includes a device wafer 210, including a first side 212a and a second side 212b, and a top wafer with an additional coupler and TSVs 220. The top wafer with an additional coupler and TSVs 220 can include a first side 222a, a second side 222b, and a bus 214 located on the first side 222a of the top device with an additional coupler and TSVs 220. A plurality of qubits 216 are located on the first side 212a of the device wafer 210, and a first plurality of bump bonds 224 are located on the first side 222a of the top wafer with an additional coupler and TSVs 220. The first plurality of bump bonds 224 bond the top wafer with an additional coupler and TSVs 220 to the second side 212b of the device wafer 210.

In some embodiments, the bus 214, which is located on the first side 222a of the top wafer with an additional coupler and TSVs 220, connects the plurality of qubits 216, which are located on the second side 212b of the device wafer 210, via a set of top TSVs 218. The bus 214 can be formed over the second side 212b of the device wafer 210, i.e., the top surface of the device wafer 210 as shown in FIG. 2, and can be extended to the first side 210a of the device wafer 210, i.e., the bottom surfacer of the wafer device 210 as shown in FIG. 2, via the set of top TSVs 218. The set of top TSVs 218 are vertical interconnections that pass through the silicon substrate of the top wafer with an additional coupler and TSVs 220 and connect circuitry on different sides of the top wafer with an additional coupler and TSVs 220. The bus 214 can be in direct contact with the set of top TSVs 218, the first plurality of bump bonds 224. The device wafer 210 can include a third set of TSVs 228 vertically extended within the device wafer 210 and below the first plurality of bump bonds 224. In some embodiments, the top wafer with an additional coupler and TSVs 220 formed over the device wafer 210 can create a fully enclosed metal channel in which long-range connections are fabricated.

The first plurality of bump bonds 224 can be formed from a first low-temperature solder material and provided with a size and/or shape that enables an electrical connection to be made at the point of contact. The first plurality of bump bonds 224 may be utilized to mechanically and electrically connect the top wafer with an additional coupler and TSVs 220 to the device wafer 210. In some embodiments, the second side 222B of the top wafer with an additional coupler and TSVs 220 further includes a first metal layer 226.

In some embodiments, the semiconductor device 200 further includes an interposer 230. The interposer 230 has a first side 232a and a second side 232b. A second plurality of bump bonds 234 are located on the second side 232b of the interposer 230. The second plurality of bump bonds 234 bond, i.e., connect, the second side 232b of the interposer 230 with the first side 212a of the device wafer 210.

The second plurality of bump bonds 234 can be formed from a second low-temperature solder material, which can be different from the low-temperature solder material used to make the first plurality of bump bonds 224, and provided with a size and/or shape that enables an electrical connection to be made at the point of contact. The second plurality of bump bonds 234 may be utilized to mechanically and electrically connect the interposer 230 to the device wafer 210. In some embodiments, the first plurality of bump bonds 224 and the second plurality of bump bonds 234 are made of different materials. That is, the first low-temperature solder material is different from the second low-temperature solder material.

In some embodiments, the interposer 230 further includes a second metal layer 236 which is extended between the second plurality of bump bonds 234. The interposer 230 can include a fourth set of TSVs 238 vertically extended within the interposer 230 and below the plurality of qubits 216 to provide connectivity between the plurality of qubits 216 and the first side 232a, i.e., the bottom side, of the interposer 230.

In some embodiments, the semiconductor device 200 includes a first carrier wafer 240 on the first side 232a of the interposer 230 and a second carrier wafer 250 on the second side 222b of the top wafer with an additional coupler and TSVs 220. That is, the first carrier wafer 240 and the second carrier wafer 250 can encapsulate the semiconductor device 200. The first carrier wafer 240 and the second carrier wafer 250 can provide structural stability to the semiconductor device 200.

In some embodiments, fabricating the TSVs, i.e., the first set of TSVs 118 and the second set of TSVs 138, as shown in FIG. 1, and the top set of TSVs 218 and the third set of TSVs 238, as shown in FIG. 2, starts by etching holes through the wafer. This can be done using deep reactive ion etching (DRIE) or other etching techniques. The etching process creates vertical holes that penetrate the silicon substrate. To insulate the sidewalls of the TSVs and prevent electrical shorts, a dielectric liner (not shown) is deposited inside the TSV holes. Common liner materials include silicon dioxide (SiO2) or silicon nitride (Si3N4). This liner also helps with the adhesion of subsequent layers. A thin barrier layer can be deposited inside the TSVs to prevent the diffusion of metal into the substrate. The barrier material can include tantalum (Ta) or tantalum nitride (TaN). A seed layer of metal can subsequently be deposited on top of the barrier layer. This layer provides a conductive surface for the subsequent electroplating step. In several embodiments, the TSV metal fill is achieved through electroplating, in which metal ions in a plating solution are attracted to the seed layer and form a solid metal structure inside the TSV, filling it completely.

In some embodiments, after electroplating, the excess metal on the wafer is removed by chemical mechanical polishing (CMP). This act creates a smooth and planar surface for subsequent processing.

Example Fabrication Process of Semiconductor Device with Coupler Structure

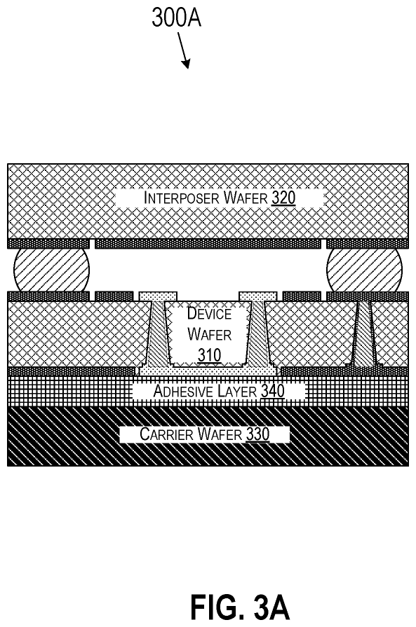

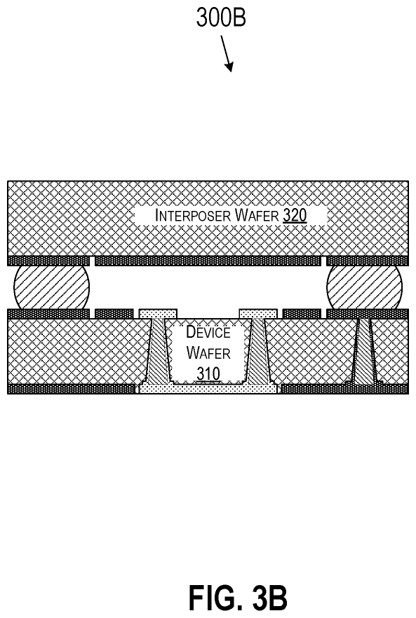

FIGS. 3A-3B illustrate processes for forming a semiconductor device, in accordance with some embodiments. In some embodiments, the semiconductor device 300A includes a device wafer 310, an interposer 320, and a carrier wafer 330. The semiconductor device 300A can include an adhesive layer 340 between the carrier wafer 330 and the device wafer 310 to connect, i.e., adhere the carrier wafer 330 to the device wafer 310. As discussed above, such a semiconductor device 300A can only connect to other devices from its exposed side, i.e., the top side. In order to increase the connectivity of the semiconductor device 300A, the carrier wafer 330 can be removed. The carrier wafer 330 can be removed by conventional methods known to a person with ordinary skills in the art, such as laser or solvent release, followed by an additional cleaning step using exposure to plasma or chemical solvents.

FIG. 3B illustrates the semiconductor device after the removal of the carrier wafer and the adhesive layer. Removing the carrier wafer can be performed by conventional techniques, however, removing the adhesive layer requires high accuracy. Any contamination, including the adhesive residue, can adversely affect the quality of the surface of the semiconductor device 300B. Thus, in some embodiments, the bottom surface of the device wafer 310, where the carrier wafer 330 and the adhesive layer 340 have been de-bonded, is cleaned to achieve a high-quality surface.

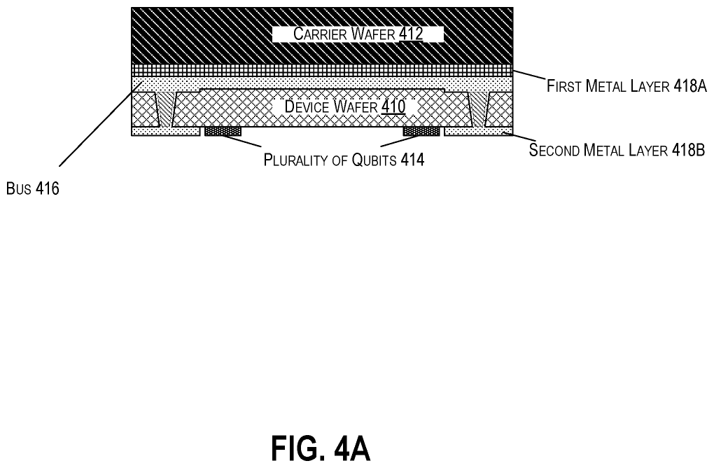

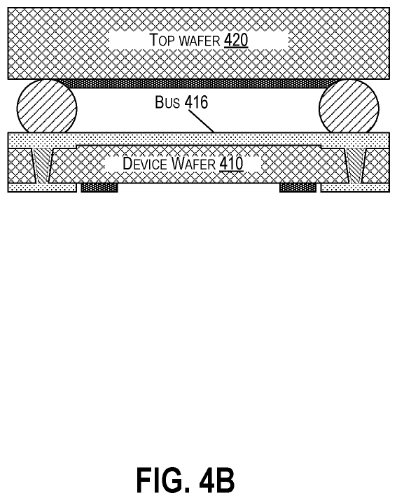

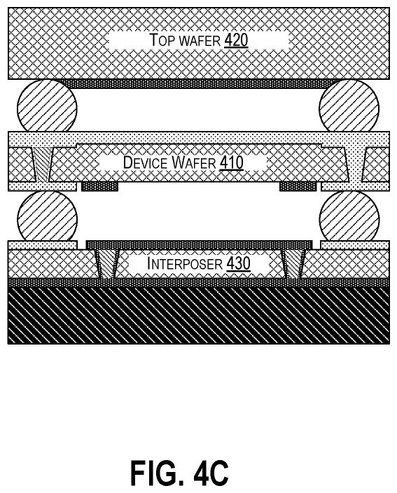

FIGS. 4A-4C illustrate the acts to form a semiconductor device, in accordance with some embodiments. FIG. 4A depicts device wafer 410 with a carrier wafer 412. The device wafer 410 can include a plurality of qubits 414, a bus 416, a first metal layer 418a, and a second metal layer 418b. In some embodiments, the carrier wafer 412 on the device wafer 410 can be de-bonded at the final stage after junction evaporation and lift-off. As shown in FIG. 4B, the device wafer 410 is bonded to the top wafer 420. In an embodiment, the top wafer 420 includes pads. As shown in FIG. 3C, the device wafer-top wafer can be bonded to an interposer 430 on the exposed side of the device wafer 410. The interposer 430 can include a set of bump bonds.

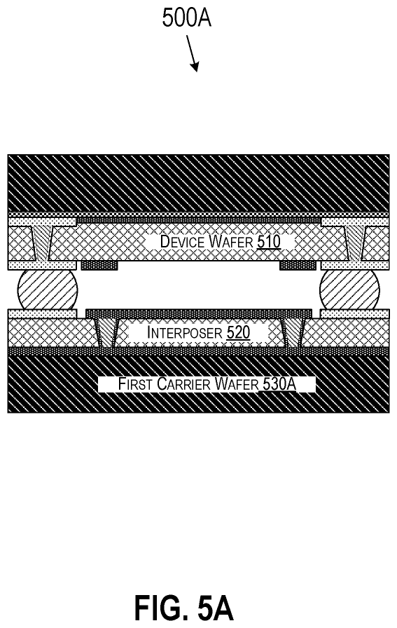

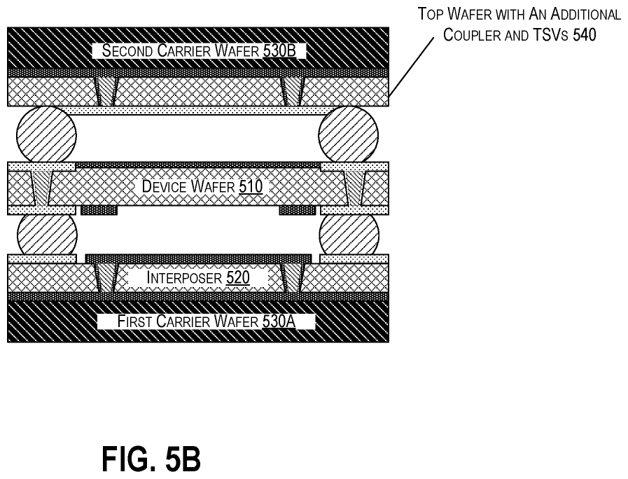

Referring to FIGS. 5A-5B now, acts to form a semiconductor device in accordance with some embodiments, are shown. As shown in FIG. 5A, the semiconductor device 500A can include a device wafer 510 and an interposer 520. A first carrier wafer 530a and a second carrier wafer 530b can encapsulate the semiconductor device 500A and provide structural stability to the semiconductor device 500A. As shown in FIG. 5B, the first carrier wafer, i.e., the carrier wafer over the device wafer 510, is de-bonded at the final stage after junction evaporation and lift-off. In some embodiments, a top wafer with additional couplers and TSVs 540 can be bonded via a cold weld process to the semiconductor device. As a result, the device wafer 510 is bonded to the interposer 520 and the top wafer with additional couplers and TSVs 540 and is not in direct contact with a carrier wafer.

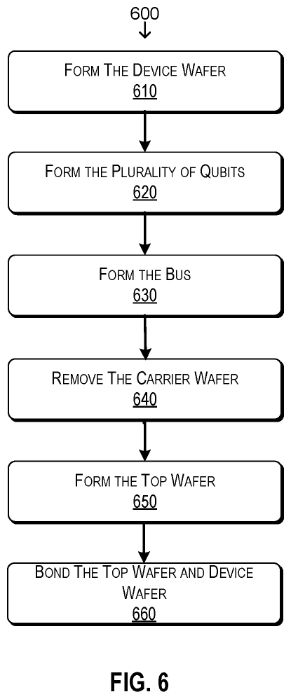

FIG. 6 illustrates an example block diagram of method 600 for forming the semiconductor device in accordance with some embodiments. Method 600 can begin when a device wafer with a first side and a second side is formed, as shown by block 610.

At block 620, a plurality of qubits on the first side of the device wafer is formed. The method 600 continues when a bus on the second side of the device wafer is formed, as shown by block 630. At block 640, a carrier wafer from the second side of the device wafer is removed.

At block 650, a top wafer having a first side and a second side is formed. The method 600 continues when the first side of the top wafer is bonded with the second side of the device wafer, as shown by block 660.

It should be noted that, while FIG. 6 illustrates an exemplary block diagram of acts to fabricate the semiconductor device, the order of acts can differ. As a non-limiting example, in some embodiments, after the device wafer is formed and TSVs and the coupler are patterned, the device wafer can be attached to a carrier wafer, which can be followed by thinning and revealing the TSVs and patterning the qubits. In such embodiments, subsequently, the device wafer is bonded to the interposer, and then the carrier wafer is released, and the surface of the semiconductor is cleaned. At this time, the top wafer, i.e., the shielding wafer, is bonded to the top of the device wafer.

As another non-limiting example, in some embodiments, after the device wafer is formed and TSVs and the coupler are patterned, the device wafer can be attached to a carrier wafer, which can be followed by thinning and revealing the TSVs and patterning the qubits. In such embodiments, the carrier wafer is released. At this time, the device wafer is bonded to the interposer, and then the top wafer, i.e., the shielding wafer, is bonded to the device wafer.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a device wafer having a first side and a second side, wherein a plurality of qubits are located on the first side of the device wafer;
a bus located on the second side of the device wafer; and
a top wafer having a first side and a second side, wherein a first plurality of bump bonds located on the first side of the top wafer bond the top wafer with the second side of the device wafer.

2. The semiconductor device of claim 1, further comprising an interposer having a first side and a second side, wherein a second plurality of bump bonds located on the second side of the interposer bond the interposer with the first side of the device wafer.

3. The semiconductor device of claim 1, wherein the bus connects the plurality of qubits via a first set of through-silicon vias (TSVs).

4. The semiconductor device of claim 1, wherein the top wafer further comprises a first metal layer between the first plurality of bump bonds.

5. The semiconductor device of claim 2, wherein the interposer further comprises a second metal layer between the second plurality of bump bonds, and a second set of TSVs.

6. The semiconductor device of claim 5, wherein the first plurality of bump bonds and the second plurality of bump bonds are made of different materials.

7. The semiconductor device of claim 2, further comprising a carrier wafer on the first side of the interposer.

8. A method for forming a semiconductor device, the method comprising:
forming a device wafer having a first side and a second side;
forming a plurality of qubits on the first side of the device wafer;
forming a bus on the second side of the device wafer;
removing a carrier wafer from the second side of the device wafer;
forming a top wafer having a first side and a second side; and
bonding the first side of the top wafer with the second side of the device wafer.

9. The method of claim 8, further comprising connecting the plurality of qubits via a first set of through-silicon vias (TSVs) by way of the bus.

10. The method of claim 8, further comprising:
forming a first plurality of bump bonds on the first side of the top wafer; and
bonding the top wafer and the device wafer via the first plurality of bump bonds.

11. The method of claim 8, further comprising:
forming an interposer having a first side and a second side,
forming a second plurality of bump bonds on the second side of the interposer; and
bonding the interposer with the first side of the device wafer via the second plurality of bump bonds.

12. The method of claim 10, further comprising forming a first metal layer on the top wafer between the first plurality of bump bonds.

13. The method of claim 11, further comprising forming a carrier wafer on the first side of the interposer.

14. The method of claim 11, further comprising:
forming a second metal layer on the interposer between the second plurality of bump bonds; and
forming a second set of TSVs on the interposer.

15. The method of claim 11, wherein a first plurality of bump bonds and the second plurality of bump bonds are made of different materials.

16. A semiconductor device, comprising:
a device wafer having a first side and a second side, wherein a plurality of qubits are located on the first side of the device wafer;
a top wafer having a first side and a second side, wherein a first plurality of bump bonds located on the first side of the top wafer bond the top wafer with the second side of the device wafer; and
a bus located on the first side of the top wafer.

17. The semiconductor device of claim 16, further comprising an interposer having a first side and a second side, wherein a second plurality of bump bonds located on the second side of the interposer bond the interposer with the first side of the device wafer.

18. The semiconductor device of claim 16, wherein the bus connects the plurality of qubits.

19. The semiconductor device of claim 17, wherein:
the interposer further comprises a metal layer between the second plurality of bump bonds, and a set of TSVs; and
the first plurality of bump bonds and the second plurality of bump bonds are made of different materials.

20. The semiconductor device of claim 17, further comprising:
a first carrier wafer on the first side of the interposer; and
a second carrier wafer on the second side of the top wafer.
